(19) United States
(12) Patent Application Publication
(10) Pub. No.: US 2024/0145103 A1
(43) Pub. Date: May 2, 2024

(54) METHOD AND SYSTEM OF PROCESSING AN INCIDENT LASER FOR THERMONUCLEAR FUSION, AND LASER FACILITY

(71) Applicants: INSTITUTE OF APPLIED PHYSICS AND COMPUTATIONAL MATHEMATICS, Beijing (CN); SHANGHAI NORMAL UNIVERSITY, Shanghai (CN)

(72) Inventors: Baifei Shen, Beijing (CN); Ke Lan, Beijing (CN); Yi Guo, Beijing (CN); Xiaomei Zhang, Beijing (CN)

(21) Appl. No.: 18/384,758

(22) Filed: Oct. 27, 2023

(30) Foreign Application Priority Data
Nov. 1, 2022 (CN) 202211357410.2

(51) Int. Cl. G21B 1/23

(52) U.S. Cl. CPC G21B 1/23; G02B 5/3083

(57) ABSTRACT

A method and system of processing an incident laser for thermonuclear fusion and a laser facility are disclosed in embodiments of the present application. The method includes: receiving an initial incident laser from a laser facility; and performing angular momentum decoherence processing on the initial incident laser, to obtain a target incident laser to be injected into a thermonuclear fusion hohlraum.

### CROSS REFERENCE

This application claims priority to Chinese Patent Application No. 202211357410.2, entitled “Processing method of incident laser, laser system, and laser facility for laser fusion” filed on Nov. 1, 2022, which is incorporated by reference in its entirety.

### TECHNICAL FIELD

The present application relates to the field of energy sources, and more particularly to a method and system of processing an incident laser for thermonuclear fusion, and laser facility.

### BACKGROUND

In laser-driven inertial confinement fusion (simplified as thermonuclear fusion), a laser is injected into a high-Z (high atomic number) material hohlraum walls through an injection hole and converted into an X-ray, and the X-ray radiates to drive and compress a spherical deuterium tritium target capsule located in the center of the hohlraum to achieve implosion and fusion ignition.

In the thermonuclear fusion, energy of a laser injected into the hohlraum is first absorbed by the hohlraum walls through laser-plasma interaction, and then is converted by a wall plasma into a driving X-ray required for the implosion of the target capsule. Therefore, laser absorption is the first important physical step of energy coupling, which is crucial to energy efficiency and is an essential issue in fusion ignition research. Further, since the hohlraum is non-vacuum, it includes plasmas ablated from the high-Z material walls and a low-Z gas filled in the hohlraum in order to suppress the motion of plasmas in a laser spot region. When the laser injected into the hohlraum passes through those plasmas, laser plasma instability is caused.

During the process of injecting lasers into the hohlraum, part of the injected lasers will scatter out of the hohlraum due to the problems such as the laser plasma instability, which will seriously reduce laser absorption efficiency, thus reducing conversion efficiency of the laser-X ray radiation. On the other hand, it greatly affects uniformity of a radiation drive field which drives ignition target capsules. As the laser plasma instability is more serious, the fraction of the reflected laser is higher, the laser absorption efficiency is lower, and the irradiation uniformity of the target capsules also becomes lower. Therefore, how to suppress the laser plasma instability is a great challenge for thermonuclear fusion ignition.

### SUMMARY

To this end, on one hand, embodiments of the present application provide a method of processing an incident laser for thermonuclear fusion, and on the other hand, embodiments of the present application provide a system of processing an incident laser for thermonuclear fusion and a laser facility, so as to reduce laser plasma instability and improve laser absorption efficiency.

In the embodiments of the present application, a method of processing an incident laser for thermonuclear fusion includes: receiving an initial incident laser from a laser facility; and performing angular momentum decoherence processing on the initial incident laser, to obtain a target incident laser to be injected into a thermonuclear fusion hohlraum.

In an embodiment of the present application, the performing angular momentum decoherence processing on the initial incident laser, to obtain a target incident laser to be injected into a thermonuclear fusion hohlraum includes: for a plurality of first sub-laser beams in the initial incident laser, converting, by using a phase plate, each first sub-laser beam into a second sub-laser beam, the second sub-laser beam having a topological charge different from other second sub-laser beams; and combining second sub-laser beams having different topological charges into a light spring, the light spring being as the target incident laser to be injected into the thermonuclear fusion hohlraum.

In an embodiment of the present application, the second sub-laser beams having different topological charges are sub-laser beams having an equidistant distribution of topological charges.

In an embodiment of the present application, the initial incident laser includes the first sub-laser beams having a same frequency and a same relative phase; and the target incident laser is a narrow-band and long-pitch light spring containing one strong spot of which a location is not time-varying.

In an embodiment of the present application, the initial incident laser includes the first sub-laser beams after temporal decoherence having an equidistant distribution of frequencies and having a same relative phase; and the target incident laser is a wide-band and short-pitch light spring containing one strong spot of which a location is time-varying.

In an embodiment of the present application, the initial incident laser includes the first sub-laser beams after temporal decoherence and spatial decoherence having an equidistant distribution of frequencies and having a random distribution of relative phases; and the target incident laser is a super light spring containing a plurality of strong spots of which locations are time-varying.

In the embodiments of the present application, a laser facility includes: a laser facility module, configured to provide an initial incident laser to be injected into a thermonuclear fusion hohlraum; and an angular momentum decoherence component, configured to perform angular momentum decoherence processing on the initial incident laser, to obtain a target incident laser to be injected into the thermonuclear fusion hohlraum.

In an embodiment of the present application, the angular momentum decoherence component includes: a phase plate stand and a plurality of phase plates arranged on the phase plate stand, a phase plate corresponding to a first sub-laser beam of a plurality of first sub-laser beams in the initial incident laser and being configured to convert the first sub-laser beam into a second sub-laser beam, the second sub-laser beam having a topological charge different from other second sub-laser beams, second sub-laser beams having different topological charges being combined into a super light spring, the super light spring being as the target incident laser to be injected into the thermonuclear fusion hohlraum.

In the embodiments of the present application, a system of processing an incident laser for thermonuclear fusion includes: a laser facility, configured to provide an initial incident laser to be injected into a thermonuclear fusion hohlraum; and an angular momentum decoherence device, configured to perform angular momentum decoherence processing on the initial incident laser, to obtain a target incident laser to be injected into the thermonuclear fusion hohlraum.

In an embodiment of the present application, the angular momentum decoherence device includes: a phase plate stand and a plurality of phase plates arranged on the phase plate stand, a phase plate corresponding to a first sub-laser beam of a plurality of first sub-laser beams in the initial incident laser and being configured to convert the first sub-laser beam into a second sub-laser beam, the second sub-laser beam having a topological charge different from other second sub-laser beams, second sub-laser beams having different topological charges being combined into a super light spring, the super light spring being as the target incident laser to be injected into the thermonuclear fusion hohlraum.

As can be seen from the above solution, in the embodiments of the present application, since angular momentum decoherence is performed on the incident laser, the laser plasma instability can be reduced, and the laser absorption efficiency can be improved.

### BRIEF DESCRIPTION OF THE DRAWINGS

The above and other features and advantages of the present application will become more apparent to those of ordinary skill in the art by describing preferred embodiments of the present application in detail with reference to the accompanying drawings in which:

FIG. 1A is a schematic diagram showing the distribution of a light spring in a two-dimensional k space.

FIG. 1B is a schematic diagram showing the distribution of Laguerre-Gaussian light in a two-dimensional k space.

FIG. 2 is a diagram of an evolution behavior of a SRS fraction for a light spring and Laguerre-Gaussian light with space.

FIG. 3 is a schematic diagram of electron energy spectrum distribution in a plasma driven by Laguerre-Gaussian light (black line) and a light spring (gray line) when an incident laser reaches x=240 μm.

FIG. 4 is an exemplary flowchart of a method of processing an incident laser for thermonuclear fusion according to an embodiment of the present application.

FIG. 5 is a schematic diagram showing a light spring combined by a plurality of sub-laser beams having different topological charges according to an embodiment of the present application.

FIG. 6 is a schematic structural diagram of a phase plate according to an embodiment of the present application.

FIG. 7 is an exemplary structural diagram of a laser facility according to an embodiment of the present application.

FIG. 8 is an exemplary structural diagram of a system of processing an incident laser for thermonuclear fusion according to an embodiment of the present application.

### DESCRIPTION OF EMBODIMENTS

In the embodiments of the present application, it is considered that laser plasma instability caused by the laser stimulated scattering in thermonuclear fusion not only causes the laser scattering out of a hohlraum and affects laser absorption efficiency, but also generates superthermal electrons to pre-heat the target capsules, which seriously influences fusion ignition and thus must be suppressed or even eliminated.

The process of laser stimulated scattering includes stimulated Brillouin scattering, stimulated Raman scattering (SRS), and two-plasmon decay. In the following, taking the SRS as an example, the hazards and influencing factors of laser plasma instability are analyzed.

When a laser propagates in a rarefied plasma, a pondermotive force perturbs an electron density distribution and stimulates an electron plasma wave, and also stimulates corresponding scattered light due to the conservation of energy and the conservation of momentum. This process is called the SRS. The term “stimulated” refers to positive feedback due to the instability of parameters in the scattering process, whereby the scattered light intensity continues to increase under continuous stimulation until saturation. The SRS converts a portion of laser energy into the electron plasma wave that heats the plasma during decay and may generate superthermal electrons. The superthermal electrons pre-heat the interior of fusion target capsules, influence quasi-isentropic compression, and cause ignition failure. At the same time, back SRS causes part of the lasers to be reflected out of the hohlraum, thereby wasting energy. In the full-scale thermonuclear fusion, the focal depth of the laser depth s is very long, that is, the Rayleigh length is very long. The instability process may continue to grow over a long laser propagation distance, thereby causing harm greater.

In a stimulated Raman process, the incident laser, the electron plasma wave, and the SRS light satisfy the conservation of energy and the conservation of momentum, given by:

ω_{L}=ωₑ+ω_{S} (1)

k_{L}=kₑ+k_{S} (2)

where ω_{L} and k_{L} are the frequency and wave number of the incident laser respectively, ωₑ and kₑ are the frequency and wave number of the electron plasma wave respectively, and ω_{S} and k_{S} are the frequency and wave number of the SRS light respectively.

It can be seen from expressions (1) and (2) that only the incident lasers with patterns satisfying matching conditions can resonate with the electron plasma wave and the SRS wave, and can provide greatest contribution to the growth of the laser plasma instability, while the incident lasers with patterns not satisfying the matching conditions make little contribution to the growth rate of the instability. Therefore, by eliminating the coherence of the incident lasers, the amount of lasers satisfying the matching conditions can be reduced, thereby reducing the growth rate of the laser plasma instability.

It can be seen from the matching relationship of expressions (1) and (2) that methods of temporal decoherence and spatial decoherence may be used.

In fact, in addition to the frequency and the wave number, the wave still has an additional parameter, i.e., angular momentum, and the above-described three waves may also satisfy the conservation of angular momentum:

L_{L}=Lₑ+L_{S} (3)

where L_{L}, Lₑ, and L_{S} denote the angular momentum of the incident laser, the angular momentum of the electron plasma wave, and the angular momentum of the SRS wave respectively. In an embodiment of the present application, an angular momentum decoherence method may be used for suppressing the laser plasma instability. The physical idea of suppressing laser plasma instability based on reducing or removing angular momentum coherence is explained below.

Take the incident laser being a linear-polarized laser as an example, which may be generalized to the circular-polarized laser. Assuming that the incident laser propagates in a x direction and a Laguerre-Gaussian mode is adopted, the amplitude of the incident laser at position x and time t may be expressed as:

a_{L}(x,t)=aₙ·e^{[iω}^{_{L}}^{t-ik}^{_{L}}^{x+il}^{_{L}}^{φ+ϕ]} (4)

where aₙ=(−1)^{p}[Cₚₗ/w(x)]·(\sqrt{2r}/w(x))^{|/|}·e^{(-r}^{²}^{/w(x)}^{²}⁾·Lₚ^{|/|}(2r²/w(x)²) denotes a spatial distribution shape of the incident laser on the transverse plane perpendicular to the propagation direction, r=\sqrt{y²+z²}, φ=tan⁻¹(z/y), w=w₀\sqrt{1+x²/x_{R}²}, Rₓ=(x²+x_{R}²)/x², Cₚₗ is the normalization constant Lₚ^{[l]}(x) is the associated Laguerre polynomial, L is the node of amplitude distribution in a radial direction, k_{L}=2π/λ_{L}, λ_{L} is the wavelength of the incident laser, w₀ is the beam-waist radius, L_{L} is the topological charge, and ϕ is the initial phase in the beam-waist plane. Since the non-correlation effect of the angular momentum is mainly considered herein, p≡0.

Here is the case where the incident laser is formed by superposition of N modes. Assume that the n^{th} mode has the frequency the wave number k_{Ln}, the topological charge l_{Ln}, and the initial phase ϕₙ (n=1, . . . , N), and then the incident laser may be written as:

$${a}_{L} ( x , t ) = {\sum }_{n = 1}^{N} {a}_{n} \cdot exp [ i {ω}_{Ln} t - {ik}_{Ln} x + {il}_{Ln} φ + {ϕ}_{n} ] \qquad ( 5 )$$

For simplicity, let aₙ≡a₀, ϕₙ≡0, and for the frequency, there is ω_{Ln}=ω₁+ω_{L0}(n−1)ε₁, the center frequency ω_{L0}=ω₁, the frequency of the first mode is ω_{L1}, the frequency spacing between different modes is ω_{L0}=ω₁, and the total frequency bandwidth is Δω=(N−1)ω_{L0}ε₁, where ε₁ is a constant that determines the frequency bandwidth gap, and Δω/ω_{L0}«1. For the topological charge, there is l_{Ln}+l₁+l_{L0}(n−1)ε₂ the central topological charge is l_{L0}, the topological charge of the first mode is l_{L1}, the topological charge spacing between different modes is l_{L0}ε₂, and the total topological charge dispersion is Δl=l_{L0}(N−1)ε₂, where ε₂ is a constant that determines the topological charge dispersion spacing, and l_{L0}ε₂ is a constant. For example, l_{L0}ε₂=1.

A light formed by superposition of N modes having the same initial phase and equally spaced topological charges is referred to as a light spring. In embodiments of the present application, a new concept of super light spring is proposed. The decoherence of the super light spring is implemented in all aspects, such as angular momentum, time, and space. The frequency is randomly distributed in a certain range, the initial phase is randomly distributed, and the topological charge is randomly distributed in a certain range. As a result, the laser plasma instability can be suppressed at a very low level.

Based on expression (5), the amplitude of the light spring superimposed by the N modes may be obtained by:

$${a}_{L} ( x , r , φ , t ) = {a}_{0} ( r ) \frac{sin [ \frac{N ( {ε}_{1} {ω}_{L 0} t - {ε}_{1} {k}_{L 0} x - {ε}_{2} {l}_{L 0} φ )}{2} ]}{sin [ \frac{{ε}_{1} {ω}_{L 0} t - {ε}_{1} {k}_{L 0} x - {ε}_{2} {l}_{L 0} φ}{2} ]} \qquad ( 6 )$$

This means that if an incident laser having only one mode and a pulse length T₀ is changed to a light spring having N modes, the pulse length of each mode is reduced to be T₀/N, and the angular momentum dispersion is reduced to be 2π/N.

For non-relativistic lasers, SRS may be described by the following expressions:

$$( \frac{{\partial }^{2}}{\partial {t}^{2}} - {c}^{2} {∇}^{2} + {ω}_{pe}^{2} ) \tilde{a} = - {\tilde{n}}_{e} {a}_{L} \qquad ( 7 )$$

$$( \frac{{\partial }^{2}}{\partial {t}^{2}} + {ω}_{pe}^{2} - 3 {v}_{e}^{2} {∇}^{2} ) {\tilde{n}}_{e} = {n}_{0} {∇}^{2} ( {a}_{L} \cdot \tilde{a} ) \qquad ( 8 )$$

where ωₚₑ is the frequency of the electron plasma wave, α_{L} is the vector potential of the incident laser, ã and ñₑ are the vector potential of the backscattered laser and the plasma density perturbation respectively, and n₀=ωₚₑ²/4πe. The radial gradient is ignored herein, but the scattered wave ˜exP(iωt−ikx+ilφ) is considered. Therefore, for the low-frequency scattered wave, the following expression may be obtained:

$${ω}^{2} - {ω}_{l}^{2} = \frac{{k}^{2} {c}^{2} {ω}_{pe}^{2} {a}_{0}^{2}}{4} {\sum }_{n = 1}^{N} \frac{1}{{( ω - {ω}_{Ln} )}^{2} - {( k - {k}_{Ln} )}^{2} {c}^{2} + \frac{{( l - {l}_{Ln} )}^{2}}{{r}^{2}} {c}^{2} - {ω}_{pe}^{2}} \qquad ( 9 )$$

where ωₗ is the frequency of the electron Langmuir wave. It can be seen that the dispersion relationship depends on a radial location. For a vortex light or a light spring, the radius R of the peak amplitude is used herein for estimation. Assuming that only one mode (ω_{L0}, k_{L0}, l_{L0}) resonates, then:

$${( {ω}_{l} - {ω}_{L 0} )}^{2} - {( k - {k}_{L 0} )}^{2} {c}^{2} + \frac{{( l - {l}_{L 0} )}^{2}}{{R}^{2}} {c}^{2} - {ω}_{pe}^{2} = 0 \qquad ( 10 )$$

And ω is written into ω=ω₁+δω=ωₗ+iγₛ, where δω«ωₗ. In consideration of ε₂=0, an expression for the instability growth rate γₛ may be obtained from expression (9):

$${γ}_{s} \approx \frac{{k}_{l} {ca}_{0}}{4} {( \frac{{ω}_{pe}^{2}}{{ω}_{l} {ω}_{s 0}} )}^{\frac{1}{2}} {\sqrt{N} [ 1 - \frac{{( N {ε}_{1} {ω}_{L 0} )}^{2}}{3 {{γ}_{s}}^{2}} ]}^{\frac{1}{2}} \approx {γ}_{0} [ 1 - \frac{{( Δω )}^{2}}{6 {{γ}_{s}}^{2}} ] \qquad ( 11 - 1 )$$

In consideration of ε₁=0, an expression for the instability growth rate γₛ may be obtained from expression (9):

$${γ}_{s} \approx \frac{{k}_{l} {ca}_{0}}{4} {( \frac{{ω}_{pe}^{2}}{{ω}_{l} {ω}_{s 0}} )}^{\frac{1}{2}} {\sqrt{N} [ 1 - \frac{1}{3} {( \frac{N {ε}_{2} {l}_{L 0}^{2} {c}^{2}}{{ω}_{s 0} {γ}_{s} {R}^{2}} )}^{2} ]}^{\frac{1}{2}} \approx {γ}_{0} [ 1 - \frac{1}{6} {( \frac{{l}_{L 0} Δ {lc}^{2}}{{ω}_{s 0} {γ}_{s} {R}^{2}} )}^{2} ] \qquad ( 11 - 2 )$$

where ωₛ=ω_{L0}−ωₗ is the frequency of the SRS wave. Herein, in order to calculate the growth rate, it is assumed that Δω/ω_{L0}«1 and Δl/l_{L0}»1.

For the incident laser superimposed by N modes, the peak laser amplitude is Na₀. From the above expressions (11-1) and (11-2), it can be seen that there are two incoherent terms for reducing γₛ, where the term in the expression (11-1) is the frequency bandwidth Δω, and the term in the expression (11-2) is the topological charge dispersion XL It is to be noted that the term Δl is dominant when Δl>(1/l_{L0})(ωₛ₀/ω_{L0})(2πR/λ_{L0})²(Δω/ω_{L0}). Since Δω/ω_{L0}«1, the dominance of the term Δl is easily achieved.

In an embodiment of the present application, a three-dimensional particle simulation is performed using an EPOCH program. As an example, in order to reduce the simulation time, l₁=3, and N=7. Therefore, an average topological charge is l̅=l_{L0}=6. In real experiments, a larger l̅ may be adopted. To simplify the problem, the amplitude distributions of the modes on the cross section are set to be the same:

$${a}_{n} ≡ {a}_{0} = {{a}_{00} ( \frac{\sqrt{2} r}{{w}_{0}} )}^{T} exp ( - \frac{{r}^{2}}{{w}_{0}^{2}} ) \qquad ( 12 )$$

In order to reduce the simulation time, a₀₀=0.6, and w₀=10 μm. The central wavelength of the incident laser is λ_{L0}=800 nm (the corresponding central frequency is ω_{L0}=3.75×10¹⁴HZ) Therefore, the power of the light spring is P=0.16TW. If the frequency spacing is ω_{L0}ε₁=0.03ω_{L0}, the total frequency width is (N−1)ω_{L0}ε₁=0.18ω_{L0}. Therefore, the pitch of the light spring is Δx=2πc/(ω_{L0}ε₁)≈27 μm. The laser amplitude is configured to be invariant with time, and the pulse width is 93.3 fs. The electron density is nₑ=1.7×10²⁰ cm⁻³ (about 0.15 times of the critical density). The dimensions of a simulation module moving with time are: 60 μm (χ)×80 μm (γ)×80 μm (Z), corresponding to 600×800×800 simulation units. One particle is guaranteed in each simulation unit. A spatial region in which the plasma is located is: 15 μm<X<800 μm, −75 μm<y<75 μm, and −75 μm<Z<75 μm.

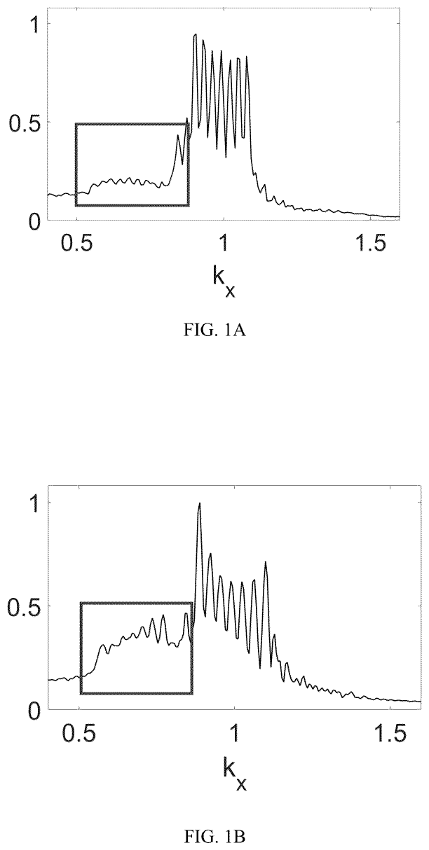

The case where the light spring has propagated 240 μm will be described below. FIG. 1A is a schematic diagram showing the distribution of a light spring in a two-dimensional k space. FIG. 1B is a schematic diagram showing the distribution of Laguerre-Gaussian light in a two-dimensional k space. The abscissa in FIG. 1A and FIG. 1B is component X of the wave number. From the two-dimensional wave number k spatial distribution shown in FIG. 1A and FIG. 1B, it can be seen that the light spring composed of seven frequencies is clearly visible and a weak signal in the left box comes from the SRS light. As a comparison, a wide-band Laguerre-Gaussian light having the same topological charge \tilde{l}, i.e., the topological charge is same but the frequency is different in its superposition pattern, is calculated. By comparing the distributions of the light spring and the Laguerre-Gaussian light in k-space at the same time, it can be seen that the latter has a strong SRS signal. This confirms the conclusion from the previous theoretical analysis that Δl decoherence plays a major role.

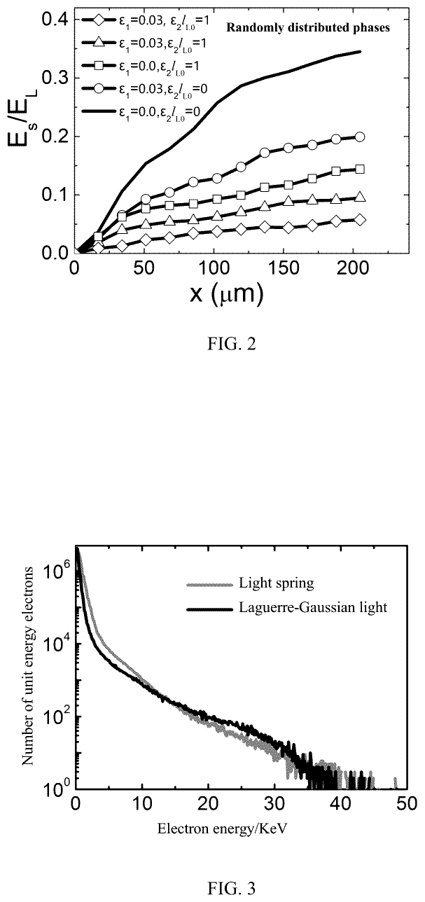

In order to clearly view the influence of the topological dispersion of the light spring (l_{L0}ϵ₂≠0) and the energy spectrum width of the Laguerre-Gaussian light (l_{L0}ε₂=0) on the SRS growth process, an evolution behavior of an SRS scattering fraction with space in difference cases is further shown in FIG. 2. FIG. 2 is a diagram of an evolution behavior of an SRS scattering fraction (ratio of scattered energy to incident laser energy) for a light spring (l_{L0}ε₂≠0) and Laguerre-Gaussian light (l_{L0}ε₂=0) with space. The abscissa in FIG. 2 is a laser propagation distance X, and the ordinate is the ratio of the scattered light amplitude E_{S} to the laser amplitude E_{L} In the case of ε₁=0.03, the SRS scattering fraction of the light spring (l_{L0}ε₂=1) is only 50% of the Laguerre-Gaussian light (l_{L0}ε₂=0). In the case of ε₁=0 (namely, single frequency), the former is only 43% of the latter. It can be seen that Δ1 dispersion plays a major role. In addition, it can be seen from FIG. 2 that the wide band (ε₁=0.03) adopted by the Laguerre-Gaussian light (l_{L0}ε₂=0) can reduce the SRS scattering fraction to 57% at a single band (ε₁=0). That is, the wide band helps to reduce the SRS scattering fraction. Further, the random phase also helps to reduce the SRS scattering fraction. It can be seen from FIG. 2 that the super light spring having the random frequency and the random phase can be used for significantly reducing the SRS scattering fraction by a factor of about 6.

The following is to verify whether the superposition of the laser sub-beams causes strong laser spots in space and time, and thus generates superthermal electrons, so as to preheat the target capsules, resulting in ignition failure. For both cases of FIG. 1, the electron energy spectrum distribution in the plasma when the plasma wave is not significantly attenuated after the laser has passed is shown herein in FIG. 3, respectively. FIG. 3 is a schematic diagram of electron energy spectrum distribution in a plasma driven by Laguerre-Gaussian light (black line) (l=6, ε₁=0.03) and a light spring (gray line) (l=3˜9, ε₁=0.03) when an incident laser reaches X=240 μm. In contrast to the Laguerre-Gaussian light, it can be seen that the light spring does not generate additional superthermal electrons. This indicates that the angular momentum divergence does not cause the generation of the superthermal electrons. Since the electron plasma wave is weaken after the angular momentum decoherence, the superthermal electrons caused by the Landau damping are also reduced. The superthermal electron reduction effect exceeds the increase of the superthermal electrons due to the local laser enhancement.

In a thermonuclear fusion device, a laser bundle is formed by superposition of a plurality of sub-laser beams. Different topological charges may be applied to the sub-laser beams, so that a plurality of Laguerre-Gaussian photon beams may be combined into a light spring bundle. Further, due to the existence of the angular momentum dispersion, the SRS can be suppressed more effectively by using the super light spring having the random phase and the random angular momentum, as shown in FIG. 2.

In order that the objects, technical solutions, and advantages of the present application will become more apparent, the technical solutions in the embodiments of the present application will be described hereinafter in detail.

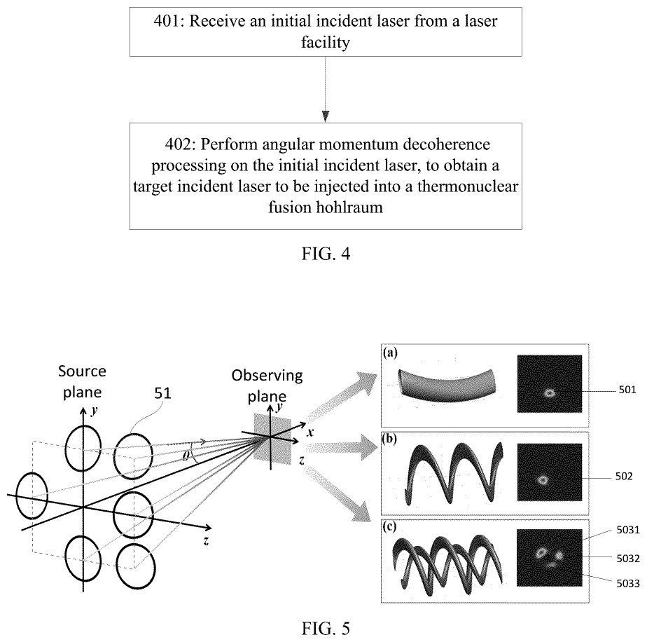

FIG. 4 is an exemplary flowchart of a method of processing an incident laser for thermonuclear fusion according to an embodiment of the present application. As shown in FIG. 4, the method may include the following steps:

Step 401: Receive an initial incident laser from a laser facility.

In embodiments of the present application, the initial incident laser from the laser facility includes a plurality of sub-laser beams. In practice, the plurality of sub-laser beams may be a plurality of sub-laser beams having the same frequency and the same relative phase, or may be a plurality of sub-laser beams having an equidistant distribution of frequencies and the same relative phase, or may also be a plurality of sub-laser beams having an equidistant distribution of frequencies and a random distribution of relative phases.

Step 402: Perform angular momentum decoherence processing on the initial incident laser, to obtain a target incident laser to be injected into a thermonuclear fusion hohlraum. The thermonuclear fusion hohlraum may be a six-hole sphere cavity or a column cavity.

In this step, as shown in FIG. 5, each of first sub-laser beams such as normal Gaussian laser beams in the initial incident laser may be converted, by using a phase plate 51, into a second sub-laser beam such as a vortex beam having a topological charge different from other second sub-laser beams. In an embodiment, N first sub-laser beams may be converted into N second sub-laser beams simultaneously. N is the number of first sub-laser beams, and N is integer. In FIG. 5, there are six phase plates configured in the source plane. Then, the second sub-laser beams having different topological charges may be combined into a light spring as the target incident laser to be injected into the thermonuclear fusion hohlraum, where the light spring is the incident laser with the angular momentum coherence removed. As a result, (a), (b), and (c) in FIG. 5 are three examples of the target incident lasers shown in the observing plane.

In an embodiment of the present application, the second sub-laser beams having different topological charges may be sub-laser beams having an equidistant distribution of topological charges.

Accordingly, if the initial incident laser includes the first sub-laser beams having the same frequency and the same relative phase, the target incident laser obtained in this step may be a narrow-band and long-pitch light spring containing one strong spot 501 of which a location is not time-varying, as shown in (a) of FIG. 5, where the light spring only has the angular momentum coherence removed.

If the initial incident laser includes the first sub-laser beams after temporal decoherence having an equidistant distribution of frequencies and having the same relative phase, the target incident laser obtained in this step may be a wide-band and short-pitch light spring containing one strong spot 502 of which a location is time-varying, as shown in (b) of FIG. 5, where the light spring has both the angular momentum coherence and the temporal coherence removed.

If the initial incident laser includes the first sub-laser beams after temporal decoherence and spatial decoherence having an equidistant distribution of frequencies and having a random distribution of relative phases, the target incident laser obtained in this step may be a super light spring containing a plurality of strong spots (5031, 5032, 5033) of which locations are time-varying, as shown in (c) of FIG. 5, where the light spring has the angular momentum coherence, the temporal coherence, and the spatial coherence removed.

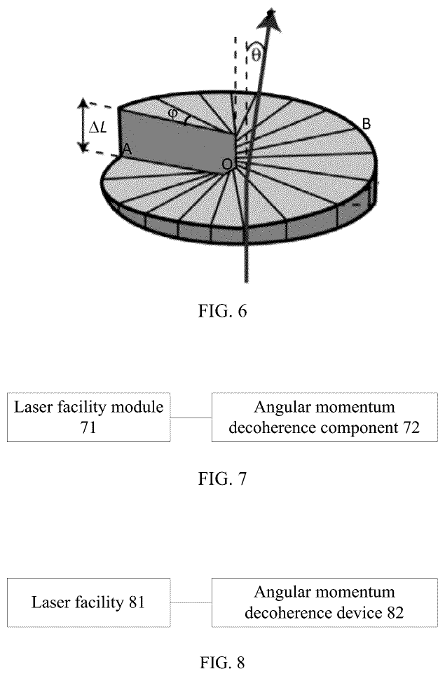

In embodiments of the present application, the structure of the phase plate may be implemented in various forms. FIG. 6 shows a schematic structural diagram of a phase plate in one example. As shown in FIG. 6, assuming that the phase plate is a circular plate, a line connecting the center O to a certain point A on the circumference is defined as a 2 axis, and an angle formed between the line connecting the center O to any point B on the circumference and the Z axis is defined as φ, the thickness at the circular plate OB may be designed as a function of the angle φ. It is assumed that the line OB circles around the phase plate, that is, φ changes from 0 to 2π, the thickness change is ΔL, and the refractive index of the phase plate is n. Then, the relative change of an optical path of the laser passing through the phase plate is (n−1)ΔL, the corresponding phase change of the laser is 2α(n−1)ΔL/λ_{L}, and the topological charge of the vortex beam is (n−1)ΔL/λ_{L}, where λ_{L} is the wavelength of the sub-laser beams. Similarly, a light fan technology may be used for realizing the conversion from the Gaussian laser to the vortex light. Accordingly, in the light spring as shown in FIG. 5, θ is the angle between the sub-beam transmission direction and the bundle transmission direction. In an example, θ<0.5°. The pitch of the light spring is Δx=2πc/(ω_{L0}ε₁), where ω_{L0}ε₁=Δω/Δl. Herein, ω_{L0} is the laser center frequency, ε₁ is a constant that determines the frequency bandwidth gap, Δω=(N−1)ω_{L0}ε₁ is the total frequency bandwidth, and Δl is the total topological charge dispersion.

In embodiments of the present application, the plurality of phase plates may have different structures, or may have similar structures but with different ΔL.

In addition, the present application further provides a laser facility. FIG. 7 is an exemplary structural diagram of a laser facility according to an embodiment of the present application. As shown in FIG. 7, the laser facility may include: a laser facility module 71 and an angular momentum decoherence component 72.

The laser facility module 71 is configured to provide an initial incident laser to be injected into a thermonuclear fusion hohlraum.

The angular momentum decoherence component 72 is configured to perform angular momentum decoherence processing on the initial incident laser, to obtain a target incident laser to be injected into the thermonuclear fusion hohlraum.

In embodiments of the present application, the angular momentum decoherence component 72 may include: a phase plate stand (not shown in FIG. 7) and a plurality of phase plates (not shown in FIG. 7) arranged on the phase plate stand. A phase plate corresponds to a first sub-laser beam of a plurality of first sub-laser beams in the initial incident laser and is configured to convert the first sub-laser beam into a second sub-laser beam, the second sub-laser beam having a topological charge different from other second sub-laser beams, whereby the second sub-laser beams having different topological charges are combined into a light spring. The light spring is the target incident laser to be injected into the thermonuclear fusion hohlraum. In embodiments of the present application, the second sub-laser beams having different topological charges may be sub-laser beams having an equidistant distribution of topological charges.

In an embodiment of the present application, when the initial incident laser includes the first sub-laser beams having the same frequency and the same relative phase, the target incident laser is a narrow-band and long-pitch light spring containing one strong spot of which a location is not time-varying. When the initial incident laser includes the first sub-laser beams after temporal decoherence having an equidistant distribution of frequencies and having the same relative phase, the target incident laser is a wide-band and short-pitch light spring containing one strong spot of which a location is time-varying. When the initial incident laser includes the first sub-laser beams after temporal decoherence and spatial decoherence having an equidistant distribution of frequencies and having a random distribution of relative phases, the target incident laser is a super light spring containing a plurality of strong spots of which locations are time-varying.

In addition, a system of processing an incident laser for thermonuclear fusion may be further provided in the present application. FIG. 8 is an exemplary structural diagram of a system of processing an incident laser for thermonuclear fusion according to an embodiment of the present application. As shown in FIG. 8, the system may include: a laser facility 81 and an angular momentum decoherence device 82.

The laser facility 81 is configured to provide an initial incident laser to be injected into a thermonuclear fusion hohlraum.

The angular momentum decoherence device 82 is configured to perform angular momentum decoherence processing on the initial incident laser, to obtain a target incident laser to be injected into the thermonuclear fusion hohlraum.

In embodiments of the present application, the angular momentum decoherence device 82 may include: a phase plate stand (not shown in FIG. 8) and a plurality of phase plates (not shown in FIG. 8) arranged on the phase plate stand. A phase plate corresponds to a first sub-laser beam of a plurality of first sub-laser beams in the initial incident laser and is configured to convert the first sub-laser beam into a second sub-laser beam, the second sub-laser beam having a topological charge different from other second sub-laser beams, whereby the second sub-laser beams having different topological charges are combined into a light spring. The light spring is the target incident laser to be injected into the thermonuclear fusion hohlraum. In embodiments of the present application, the sub-laser beams having different topological charges may be sub-laser beams having an equidistant distribution of topological charges.

In an embodiment of the present application, when the initial incident laser includes the first sub-laser beams having the same frequency and the same relative phase, the target incident laser is a narrow-band and long-pitch light spring containing one strong spot of which a location is not time-varying. When the initial incident laser includes the first sub-laser beams after temporal decoherence having an equidistant distribution of frequencies and having the same relative phase, the target incident laser is a wide-band and short-pitch light spring containing one strong spot of which a location is time-varying. When the initial incident laser includes the first sub-laser beams after temporal decoherence and spatial decoherence having an equidistant distribution of frequencies and having a random distribution of relative phases, the target incident laser is a super light spring containing a plurality of strong spots of which locations are time-varying.

The foregoing merely illustrates a few embodiments of the present application and is not intended to limit the present application. In practical application, other specific embodiments may be transformed according to the description in the embodiments of the present application, and any modifications, equivalents, improvements, etc. made within the spirit and principles of the present application should be included in the scope of protection of the present application.

What is claimed is:

1. A method of processing an incident laser for thermonuclear fusion, comprising:
receiving an initial incident laser from a laser facility; and
performing angular momentum decoherence processing on the initial incident laser, to obtain a target incident laser to be injected into a thermonuclear fusion hohlraum.

2. The method according to claim 1, wherein the performing angular momentum decoherence processing on the initial incident laser, to obtain a target incident laser to be injected into a thermonuclear fusion hohlraum comprises:
for a plurality of first sub-laser beams in the initial incident laser, converting, by using a phase plate, each first sub-laser beam into a second sub-laser beam, the second sub-laser beam having a topological charge different from other second sub-laser beams; and
combining second sub-laser beams having different topological charges into a light spring, the light spring being as the target incident laser to be injected into the thermonuclear fusion hohlraum.

3. The method according to claim 2, wherein the second sub-laser beams having different topological charges are sub-laser beams having an equidistant distribution of topological charges.

4. The method according to claim 3, wherein the initial incident laser comprises the first sub-laser beams having a same frequency and a same relative phase; and
the target incident laser is a narrow-band and long-pitch light spring containing one strong spot of which a location is not time-varying.

5. The method according to claim 3, wherein the initial incident laser comprises the first sub-laser beams after temporal decoherence having an equidistant distribution of frequencies and having a same relative phase; and
the target incident laser is a wide-band and short-pitch light spring containing one strong spot of which a location is time-varying.

6. The method according to claim 3, wherein the initial incident laser comprises the first sub-laser beams after temporal decoherence and spatial decoherence having an equidistant distribution of frequencies and having a random distribution of relative phases; and
the target incident laser is a super light spring containing a plurality of strong spots of which locations are time-varying.

7. A laser facility, comprising:
a laser facility module, configured to provide an initial incident laser to be injected into a thermonuclear fusion hohlraum; and
an angular momentum decoherence component, configured to perform angular momentum decoherence processing on the initial incident laser, to obtain a target incident laser to be injected into the thermonuclear fusion hohlraum.

8. The laser facility according to claim 7, wherein the angular momentum decoherence component comprises:
a phase plate stand; and
a plurality of phase plates arranged on the phase plate stand, a phase plate corresponding to a first sub-laser beam of a plurality of first sub-laser beams in the initial incident laser and being configured to convert the first sub-laser beam into a second sub-laser beam, the second sub-laser beam having a topological charge different from other second sub-laser beams, second sub-laser beams having different topological charges being combined into a light spring, the light spring being as the target incident laser to be injected into the thermonuclear fusion hohlraum.

9. A system of processing an incident laser for thermonuclear fusion, comprising:
a laser facility, configured to provide an initial incident laser to be injected into a thermonuclear fusion hohlraum; and
an angular momentum decoherence device, configured to perform angular momentum decoherence processing on the initial incident laser, to obtain a target incident laser to be injected into the thermonuclear fusion hohlraum.

10. The system according to claim 9, wherein the angular momentum decoherence device comprises:
a phase plate stand; and
a plurality of phase plates arranged on the phase plate stand, a phase plate corresponding to a first sub-laser beam of a plurality of first sub-laser beams in the initial incident laser and being configured to convert the first sub-laser beam into a second sub-laser beam, the second sub-laser beam having a topological charge different from other second sub-laser beams, second sub-laser beams having different topological charges being combined into a light spring, the light spring being as the target incident laser to be injected into the thermonuclear fusion hohlraum.
